(19) United States
(12) Patent Application Publication
(10) Pub. No.: US 2026/0313915 A1
(43) Pub. Date: Oct. 8, 2026

(54) Semiconductor structure containing RRAM and method for preparing same

(71) Applicant: Shanghai Huali Integrated Circuit Corporation, Shanghai (CN)

(72) Inventors: Shaokang YAO, Shanghai (CN); Qiwei WANG, Shanghai (CN); Haoyu CHEN, Shanghai (CN)

(73) Assignee: Shanghai Huali Integrated Circuit Corporation, Shanghai (CN)

(21) Appl. No.: 19/632,463

(22) Filed: Mar. 30, 2026

(30) Foreign Application Priority Data
Apr. 8, 2025 (CN) 2025104378154

(51) Int. Cl. H10B 63/00; H10N 70/00

(52) U.S. Cl. CPC H10B 63/30; H10B 63/84; H10N 70/063; H10N 70/841; H10N 70/8833

(57) ABSTRACT

A semiconductor structure containing an RRAM and a method for preparing the same are provided, which integrate the fabrication of the RRAM into the front-end-of-line (FEOL) process. This requires only one additional photomask to create the bottom electrode of the RRAM compared to standard HKMG process. Furthermore, the top electrode of the RRAM is formed simultaneously with the high-resistance layer during the FEOL process. This approach significantly reduces the manufacturing cost of the RRAM while also minimizing device thickness and shrinking the overall device size.

### FIELD OF THE INVENTION

The present disclosure belongs to the field of semiconductor manufacturing technology and in particular, relates to a semiconductor structure containing an RRAM and a method for preparing the same.

### BACKGROUND OF THE INVENTION

Memory devices are some of the most critical components in modern information systems, their quantities account for approximately one-third of the semiconductor chips, and economically they have formed a market exceeding one hundred billion dollars annually. The memory devices are primarily dominated by DRAM and NAND Flash.

With the advent of the era of ubiquitous intelligent connectivity, emerging applications such as artificial intelligence and smart vehicles demand higher performance for storage, driving rapid advancements in next-generation memory technologies.

Resistive Random Access Memory (RRAM or ReRAM, also known as a memristor) is a type of non-volatile memory based on the reversible switching of the electrical resistance of non-conductive materials, which can transition between high-resistance and low-resistance states under an applied electric field. In an existing RRAM device, its structure typically consists of a bottom electrode, a resistive switching layer, and a top electrode, where the resistive switching layer contains oxygen atoms. In RRAM, the mechanism of resistance switching primarily involves the formation and rupture of conductive filaments composed of oxygen vacancies. When a positive voltage is applied to the device under a specific condition, a soft breakdown occurs in the resistive switching layer, leading to the formation of conductive filaments. This soft breakdown process triggers migration of oxygen ions within the resistive switching layer under the influence of the electric field. These oxygen ions eventually accumulate at the top electrode. As the oxygen ions migrate, a large number of oxygen vacancies are generated in the resistive switching layer, forming a conductive pathway composed of these vacancies. This pathway, often referred to as a conductive filament, results in the RRAM device entering a low-resistance state (LRS). When a reverse voltage is applied to the RRAM device, the oxygen ions recombine with the oxygen vacancies, causing the device to return to a high-resistance state (HRS). In RRAM, the transition from HRS to LRS is termed the SET operation, while the reverse transition from LRS to HRS is referred to as the RESET operation.

RRAM is one of the most promising emerging non-volatile memory technologies. It features a simple device structure, straightforward operation, and offers advantages such as easy scalability, high speed, low power consumption, cost-effectiveness, and compatibility with CMOS processes.

Currently, the mainstream manufacturing method for RRAM involves integrating RRAM devices into the back-end-of-line (BEOL) process of CMOS technology by adding 2 or 3 photomasks between two metal layers. This creates a sandwich structure comprising a bottom electrode (BE), a resistive switching layer (RSL), and a top electrode (TE). As shown in the dashed box of FIG. 1, the RRAM is positioned between metal layers during the BEOL process. However, the primary obstacle to the widespread adoption of RRAM in the market remains its relatively high production cost. Therefore, reducing the production cost of RRAM is crucial for its commercial viability.

Therefore, it is necessary to provide a semiconductor structure containing an RRAM and a method for preparing the same.

### SUMMARY OF THE INVENTION

The present disclosure provides a semiconductor structure containing an RRAM and a method for preparing the same, for reducing the high production cost of RRAM.

The method includes:
providing a High-k Metal Gate (HKMG) substrate, wherein the HKMG substrate comprises a bulk, a source region disposed in the bulk, a drain region disposed in the bulk, an HKMG gate structure over the bulk, and a first dielectric layer covering the bulk and side surfaces of the HKMG gate structure;
forming a second dielectric layer covering the first dielectric layer and a top surface of the HKMG gate structure;
patterning the second dielectric layer and the first dielectric layer to form a trench penetrating the second dielectric layer and the first dielectric layer;
forming a bottom electrode, which fills the trench, wherein the bottom electrode is in contact with the drain region;
forming a resistive switching layer, a top electrode, and a hard mask layer stacked sequentially from bottom to top over the second dielectric layer over the bottom electrode away from the HKMG gate structure, wherein the resistive switching layer is in contact with the bottom electrode;
patterning the hard mask layer, the top electrode, and the resistive switching layer;
forming a third dielectric layer over the second dielectric layer, wherein the third dielectric layer covers side surfaces and a top surface of the hard mask layer, and side surfaces of the top electrode and the resistive switching layer; and
patterning the third dielectric layer, the hard mask layer, the second dielectric layer, and the first dielectric layer to form contact holes partially exposing the top electrode, the HKMG gate structure, and the source region.

Optionally, a material of the top electrode comprises TiN, and the top electrode is prepared simultaneously with a high-resistance layer.

Optionally, a material of the bottom electrode comprises TiN, TaN or W.

Optionally, a material of the resistive switching layer comprises HfO₂, Al₂O₃, TaO₂ or Ta₂O₅.

Optionally, a thickness of the top electrode ranges from 30 Å to 100 Å, a thickness of the resistive switching layer ranges from 20 Å to 100 Å, and a thickness of the bottom electrode ranges from 300 Å to 600 Å.

Optionally, after forming the bottom electrode, the method further includes flattening the bottom electrode; wherein a method of the flattening comprises a CMP method.

The semiconductor structure includes:
an HKMG substrate, wherein the HKMG substrate comprises a bulk, a source region disposed in the bulk, a drain region disposed in the bulk, an HKMG gate structure over the bulk, and a first dielectric layer covering the bulk and side surfaces of the HKMG gate structure;
a second dielectric layer, covering the first dielectric layer and a top surface of the HKMG gate structure; a trench, penetrating the second dielectric layer and the first dielectric layer;
a bottom electrode, wherein the bottom electrode fills the trench and is in contact with the drain region;
a resistive switching layer, a top electrode, and a hard mask layer stacked sequentially from bottom up over the second dielectric layer over the bottom electrode away from the HKMG gate structure, wherein the resistive switching layer is in contact with the bottom electrode;
a third dielectric layer over the second dielectric layer, wherein the third dielectric layer covers side surfaces and a top surface of the hard mask layer, and side surfaces of the top electrode and the resistive switching layer; and
contact holes, wherein the contact holes penetrate the third dielectric layer, the hard mask layer, the second dielectric layer, and the first dielectric layer, and partially expose the top electrode, the HKMG gate structure, and the source region.

Optionally, a material of the top electrode comprises TiN, the top electrode, and a high-resistance layer of the HKMG gate structure are made of the same materials, a material of the bottom electrode comprises TiN, TaN or W, and a material of the resistive switching layer comprises HfO₂, Al₂O₃, TaO₂ or Ta₂O₅.

Optionally, a thickness of the top electrode ranges from 30 Å to 100 Å, a thickness of the resistive switching layer ranges from 20 Å to 100 Å, and a thickness of the bottom electrode ranges from 300 Å to 600 Å.

As described above, the presently disclosed semiconductor structure containing the RRAM and the method for preparing the same integrate the fabrication of the RRAM into the front-end-of-line (FEOL) process. This process requires only one additional photomask from the conventional flow to create the bottom electrode of the RRAM. Furthermore, the top electrode of the RRAM is formed simultaneously with the high-resistance layer during the FEOL process. This approach significantly reduces the manufacturing cost of the RRAM while also minimizing device thickness and shrinking the overall device size.

### BRIEF DESCRIPTION OF DRAWINGS

FIG. 1 shows a schematic structural diagram of a semiconductor structure containing an RRAM in the prior art.

FIG. 2 is a flowchart illustrating a method for preparing a semiconductor structure containing an RRAM according to embodiments of the present disclosure.

FIGS. 3 to 11 are schematic structural diagrams of intermediate structures obtained after various steps of a method for preparing a semiconductor structure containing an RRAM according to embodiments of the present disclosure.

### REFERENCE NUMERALS

100 Bulk
101 Source Region
102 Drain Region
200 HKMG Gate Structure
201 HK Layer
202 MG Layer
300 Protective Layer
401 First Dielectric Layer
402 Second Dielectric Layer
403 Third Dielectric Layer
500 Trench
600 RRAM
601 Bottom Electrode
602 Resistive Switching Layer
603 Top Electrode
700 Hard Mask Layer
800 Contact Hole

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It is to be understood that the spatial relationship terms herein are intended to encompass orientations of the device in use or operation that are different from those depicted in the accompanying drawings. The embodiments may include instances where the first and second features are formed in direct contact, as well as instances where additional features are formed between the first and second features, such that the first and second features may not be in direct contact. Furthermore, when a layer is referred to as being “between” two layers, it may be the only layer between the two layers, or there may be one or more intervening layers present.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components'layout may also be more complicated.

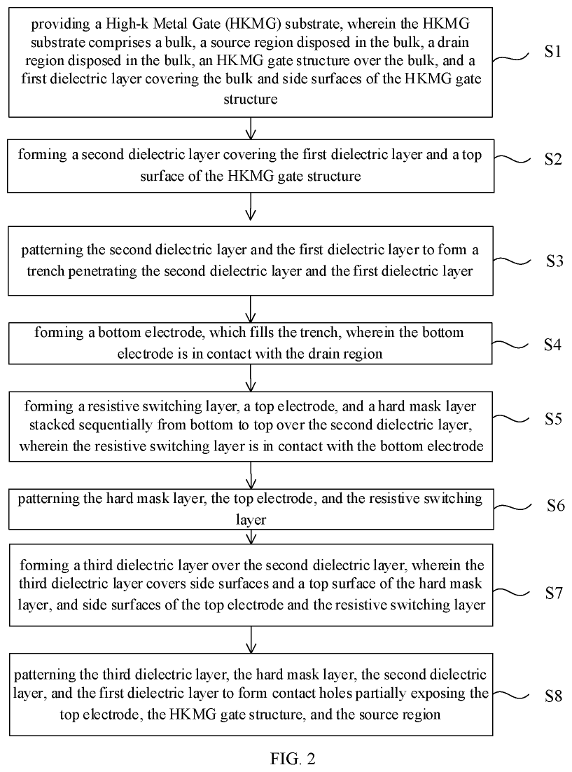

As shown in FIG. 2, the present disclosure provides a method for preparing a semiconductor structure containing an RRAM, and the method includes steps S1-S8:
S1: providing an HKMG substrate, wherein the HKMG substrate comprises a bulk, a source region disposed in the bulk, a drain region disposed in the bulk, an HKMG gate structure on the surface the bulk, and a first dielectric layer on the bulk and side surfaces of the HKMG gate structure;
S2: forming a second dielectric layer covering the first dielectric layer and a top surface of the HKMG gate structure;
S3: patterning the second dielectric layer and the first dielectric layer to form a trench penetrating the second dielectric layer and the first dielectric layer;
S4: forming a bottom electrode by filling the trench, wherein the bottom electrode is in contact with the drain region;
forming a resistive switching layer, a top electrode, and a hard mask layer stacked sequentially from bottom up over the second dielectric layer over the bottom electrode away from the HKMG gate structure, wherein the resistive switching layer is in contact with the bottom electrode;
S6: patterning the hard mask layer, the top electrode and the resistive switching layer;
S7: forming a third dielectric layer over the second dielectric layer, wherein the third dielectric layer covers side surfaces and a top surface of the stacked up patterned hard mask layer, and side surfaces of the top electrode and the resistive switching layer; and
S8: patterning the third dielectric layer, the hard mask layer, the second dielectric layer, and the first dielectric layer to form contact holes partially exposing the top electrode, the HKMG gate structure, and the source region.

The presently disclosed method for preparing the semiconductor structure containing the RRAM integrates the fabrication of the RRAM into the FEOL process. This requires only one additional photomask in creating the bottom electrode of the RRAM. Furthermore, the top electrode of the RRAM is formed simultaneously with the high-resistance layer during the FEOL process. This approach significantly reduces the manufacturing cost of the RRAM while also minimizing device thickness and shrinking the overall device size.

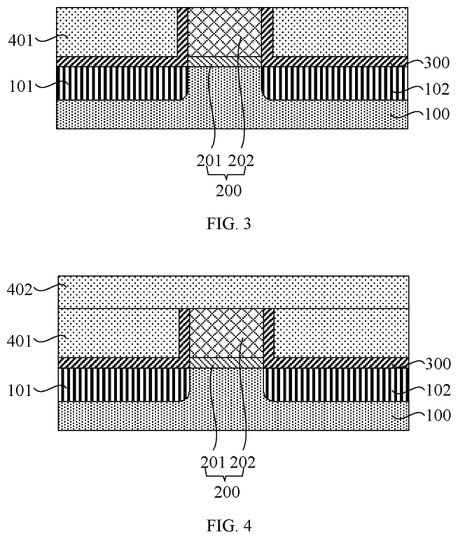

The method is hereinafter further described in connection with FIGS. 3 to 11 of the accompanying drawings of the specification.

First, referring to FIGS. 2 and 3, step S1 is performed by providing an HKMG substrate; the HKMG substrate includes a bulk 100, a source region 101 disposed in the bulk 100, a drain region 102 disposed in the bulk 100, an HKMG gate structure 200 disposed on the surface of the bulk 100, and a first dielectric layer 401 disposed on the side surfaces of the HKMG gate structure 200 and on the surface of the bulk 100 outside the HKMG gate structure 200.

Specifically, referring to FIG. 3, the HKMG gate structure 200 comprises a high-dielectric-constant (High-K or HK) layer 201 and a metal gate (MG) layer 202. The doping type of the bulk 100, the doping types of the source region 101 and the drain region 102, the specific structure and materials forming the HKMG gate structure 200, and the preparation sub-steps of the HKMG substrate may be adjusted in practice as needed.

As an example, as shown in FIG. 3, the first dielectric layer 401 is a silicon oxide layer, and preferably the HKMG substrate further includes a protective layer 300 covering surfaces of the source region 101, the drain region 102 and the side surfaces of the HKMG gate structure 200. As an example, the protective layer 300 is a silicon nitride layer. The HKMG gate structure 200 may also include side walls and the like.

Next, referring to FIGS. 2 and 4, step S2 is performed by forming a second dielectric layer 402 covering the first dielectric layer 401, a top surface of the HKMG gate structure 200, and the top edges of the protective layer 300.

Specifically, as an example, the second dielectric layer 402 is made of silicon oxide, and preferably the second dielectric layer 402 has a thickness ranging from 100Å to 300Å, such as 100Å, 200Å, 300Å, etc.

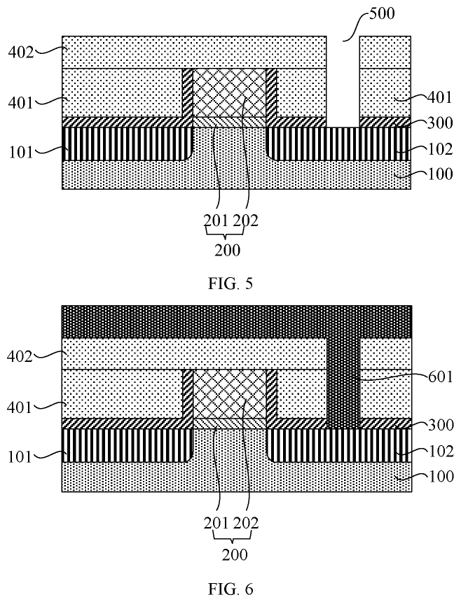

Next, referring to FIGS. 2 and 5, step S3 is performed by patterning the second dielectric layer 402 and the first dielectric layer 401 to form a trench 500 penetrating the second dielectric layer 402, the first dielectric layer 401, and the protective layer 300.

Specifically, one layer of photoresist (not shown) is introduced to pattern the trench 500 partially exposing the drain region 102 using photolithography and etching, to facilitate subsequent preparation of the bottom electrode 601.

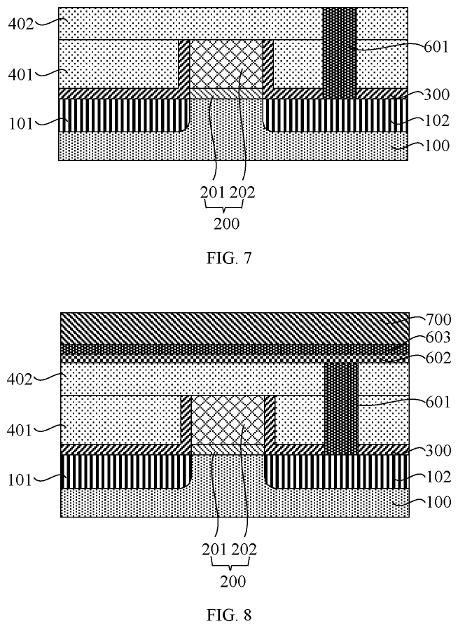

Next, referring to FIG. 2, FIG. 6 and FIG. 7, step S4 is performed by forming the bottom electrode 601, which fills the trench 500 and leaves a layer on the surface of the second dielectric layer; the bottom electrode 601 is in contact with the drain region 102.

Specifically, a material of the bottom electrode 601 may include, e.g., TiN, TaN, W, etc. ; a thickness of the bottom electrode 601 in the trench may range from 300 Å to 600 Å, e.g., 300 Å, 400 Å, 500 Å, 600 Å, etc.

Referring to FIGS. 6 and 7, after forming the bottom electrode 601, the method further includes removing the metal material layer from the surface of the second dielectric layer 402 outside the bottom electrode 601 in the trench 500, using, for example, a chemical-mechanical polishing (CMP) process, in order to expose the second dielectric layer 402 for subsequent operations.

Next, referring to FIGS. 2 and 8, step S5 is performed by forming a resistive switching layer 602, a top electrode 603, and a hard mask layer 700 stacked sequentially from bottom up on the second dielectric layer 402 over the bottom electrode away from the HKMG gate structure. The resistive switching layer 602 is in direct contact with the bottom electrode 601.

Specifically, a material of the resistive switching layer 602 may include, e.g., HfO₂, Al₂O₃, TaO₂ or Ta₂O₅, etc.; a thickness of the resistive switching layer 602 may range from 20 Å to 100 Å, e.g., 20 Å, 40 Å, 50 Å, 60 Å, 80 Å, 100 Å, etc. A material of the hard mask layer 700 may include, e.g., silicon nitride; a thickness of the hard mask layer 700 may range from 200 Å to 500 Å, e.g., 200 Å, 300 Å, 400 Å, 500 Å, etc.

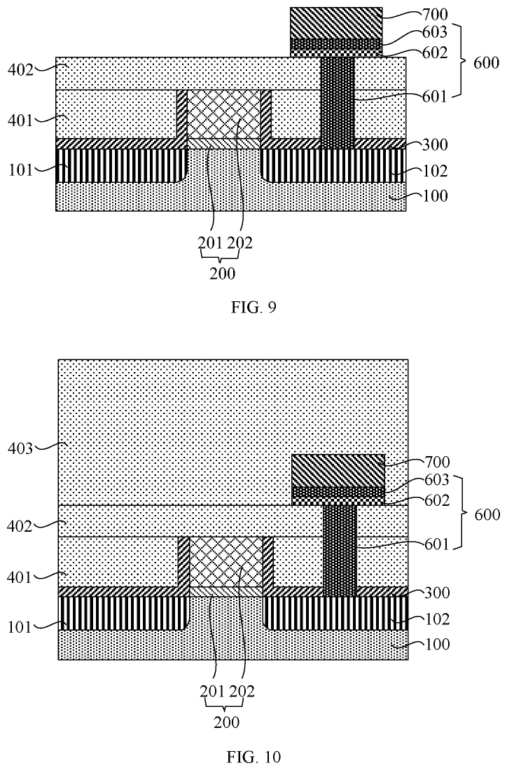

Next, referring to FIGS. 2 and 9, step S6 is performed by patterning the hard mask layer 700, the top electrode 603, and the resistive switching layer 602, so as to form an RRAM 600 including a stack of patterned hard mask layer, a patterned top electrode, and a patterned resistive switching layer 602.

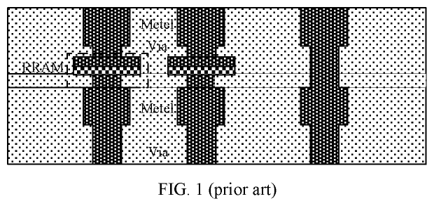

Specifically, when preparing an HKMG device, in the FEOL process, it is often necessary to prepare a high-resistance layer (not shown in FIG. 1). In the present disclosure, while preparing that high-resistance layer, the top electrode 603 is simultaneously prepared using the same material as the high-resistance layer, e.g., TiN. The high-resistance layer may be part of the HKMG gate structure 200.

In the present disclosure, only one extra photomask is added to carry out the patterning of the bottom electrode 601; the formation of the resistive switching layer 602, the top electrode 603, and the hard mask layer 700 may also be carried out based on manufacturing processes of patterning the high-resistance layer in the current manufacturing flow. The resistive switching layer 602 may be regarded as a part of the current high-resistance layer, whereby the present disclosure may reduce the production cost of the RRAM 600, and may further reduce the device thickness.

Next, referring to FIGS. 2 and 10, step S7 is performed by forming a third dielectric layer 403 on the second dielectric layer 402, wherein the third dielectric layer 403 covers the stack of the hard mask layer 700, the top electrode 603, and the resistive switching layer 602.

Specifically, a material of the third dielectric layer 403 may include silicon oxide, and a thickness of the third dielectric layer 403 may range from 1000 Å to 3000 Å, e.g., 1000 Å, 2000 Å, 3000 Å, etc.; it is preferred to include a CMP process after forming the third dielectric layer 403 to flatten the third dielectric layer 403.

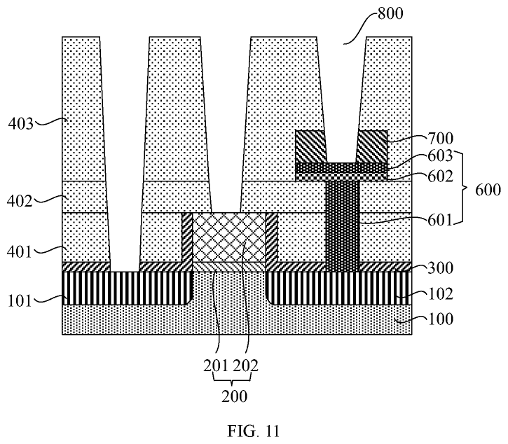

Next, referring to FIGS. 2 and 11, step S8 is performed by patterning the third dielectric layer 403, the hard mask layer 700, the second dielectric layer 402, and the first dielectric layer 401 to form contact holes 800 partially exposing the top electrode 603, the HKMG gate structure 200, and the source region 101.

Specifically, the contact holes 800 may be formed by photolithography and etching, and are used to facilitate subsequent electrical connection.

Referring to FIGS. 3 to 11, the present disclosure also provides a semiconductor structure containing an RRAM, and the semiconductor structure includes:
an HKMG substrate, wherein the HKMG substrate includes a bulk 100, a source region 101 disposed in the bulk 100, a drain region 102 disposed in the bulk 100, an HKMG gate structure 200 over the bulk 100, and a first dielectric layer 401 on the bulk 100, the protective layer 300 outside the side surfaces of the HKMG gate structure 200;
a second dielectric layer 402, on the top surface of the first dielectric layer 401 and a top surface of the HKMG gate structure 200;
a trench 500, penetrating the second dielectric layer 402 and the first dielectric layer 401, and the protective layer 300 on the drain region 102;
a bottom electrode 601, wherein the bottom electrode 601 fills the trench 500 and is in contact with the drain region 102;
a resistive switching layer 602, a top electrode 603, and a hard mask layer 700 stacked sequentially from bottom to top on the second dielectric layer 402 over the bottom electrode away from the HKMG gate structure, wherein the resistive switching layer 602 is in direct contact with the bottom electrode 601;
a third dielectric layer 403 on the second dielectric layer 402, wherein the third dielectric layer 403 covers the side surfaces and the top surface of the hard mask layer 700, the side surfaces of the top electrode 603 as well as the resistive switching layer 602;
contact holes 800, wherein the contact holes 800, the first contact hole penetrates the third dielectric layer 403 and the hard mask layer 700 in the RRAM stack exposing the top electrode, a second contact hole penetrates the third dielectric layer 403 and the second dielectric layer 402 exposing the HKMG gate structure 200, and a third contact hole penetrates the third dielectric layer 403, the second dielectric layer 402, the first dielectric layer 401, and the protective layer 300 exposing the source region 101.

Specifically, the RRAM 600 may or may not be prepared using above-described steps. As an example, the RRAM 600 is prepared using the above-described steps.

As an example, a material of the top electrode 603 may include TiN, and the top electrode 603 is made of the same material as the high-resistance layer of the HKMG gate structure 200; a material of the bottom electrode 601 may include TiN, TaN or W; a material of the resistive switching layer 602 may include HfO₂, Al₂O₃, TaO₂ or Ta₂O₅.

As an example, a thickness of the top electrode 603 may range from 30 Å to 100 Å, a thickness of the resistive switching layer 602 may range from 20 Å to 100 Å, and a thickness of the bottom electrode 601 may range from 300 Å to 600 Å.

As described above, the presently disclosed semiconductor structure containing the RRAM and the method for preparing the same integrate the fabrication of the RRAM into the FEOL process. This requires only one additional photomask to create the bottom electrode of the RRAM. Furthermore, the top electrode of the RRAM is formed simultaneously with the high-resistance layer during the FEOL process. This approach significantly reduces the manufacturing cost of the RRAM while also minimizing device thickness and shrinking the overall device size.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A method for preparing a semiconductor Resistive Random-Access Memory
(RRAM), comprising:
providing a High-k Metal Gate (HKMG) substrate, wherein the HKMG substrate comprises a bulk, a source region disposed in the bulk, a drain region disposed in the bulk, an HKMG gate structure disposed over the bulk, a protective layer on sides of the HKMG gate structure, top surface of the source region and top surface of the drain region, and a first dielectric layer disposed on the protective layer at the side surfaces of the HKMG gate structure and the protective layer on the bulk;
forming a second dielectric layer on the first dielectric layer and a top surface of the HKMG gate structure;
patterning the second dielectric layer and the first dielectric layer to form a trench penetrating the second dielectric layer, the first dielectric layer, and the protective layer, wherein the trench is above the drain region and away from the HKMG gate structure;
forming a bottom electrode metal layer on the second dielectric layer, wherein the bottom electrode metal layer fills the trench to form a bottom electrode, wherein the bottom electrode is in contact with the drain region;
forming a resistive switching layer, a top electrode, and a hard mask layer stacked sequentially from bottom up over the second dielectric layer, wherein the resistive switching layer is in direct contact with the bottom electrode;
patterning the hard mask layer, the top electrode, and the resistive switching layer above the bottom electrode to form an RRAM stack, wherein the RRAM stack is over the drain region and set away from the HKMG gate structure;
forming a third dielectric layer over the second dielectric layer, wherein the third dielectric layer covers side surfaces and a top surface of the RRAM stack; and
patterning the third dielectric layer, the hard mask layer, the second dielectric layer, the first dielectric layer, and the protective layer to form three contact holes, wherein a first contact hole penetrates the third dielectric layer and the hard mask layer in the RRAM stack exposing the top electrode, a second contact hole penetrates the third dielectric layer and the second dielectric layer exposing the HKMG gate structure, and a third contact hole penetrates the third dielectric layer, the second dielectric layer, the first dielectric layer, and the protective layer exposing the source region.

2. The method according to claim 1, wherein a material of the top electrode comprises TiN, and the top electrode is prepared simultaneously with a high-resistance layer.

3. The method according to claim 1, wherein a material of the bottom electrode comprises TiN, TaN or W.

4. The method according to claim 1, wherein a material of the resistive switching layer comprises HfO₂, Al₂O₃, TaO₂ or Ta₂O₅.

5. The method according to claim 1, wherein a thickness of the top electrode ranges from 30 Å to 100 Å, a thickness of the resistive switching layer ranges from 20 Å to 100 Å, and a thickness of the bottom electrode ranges from 300 Å to 600 Å.

6. The method according to claim 1, wherein materials of the first dielectric layer, the second dielectric layer and the third dielectric layer each comprise silicon oxide;
and wherein a material of the hard mask layer comprises silicon nitride.

7. The method according to claim 1, after forming the bottom electrode metal layer, further comprising removing the bottom electrode metal layer, wherein the removing comprises a CMP method.

8. A semiconductor structure containing a Resistive Random-Access Memory
(RRAM) device, comprising:
an HKMG substrate, wherein the HKMG substrate comprises a bulk, a source region disposed in the bulk, a drain region disposed in the bulk, an HKMG gate structure disposed over the bulk, a protective layer on side surfaces of the HKMG gate structure as well as on top surface of the bulk, and a first dielectric layer disposed on the protective layer at the side surfaces of the HKMG gate structure and on the bulk;
a second dielectric layer, disposed on the first dielectric layer and a top surface of the HKMG gate structure;
a trench, disposed over the drain region, penetrating the second dielectric layer, the first dielectric layer, and the protective layer;
a bottom electrode, wherein the bottom electrode fills the trench and is in contact with the drain region;
an RRAM stack, comprising a resistive switching layer in direct contact with the bottom electrode, a top electrode, and a hard mask layer, stacked sequentially from bottom up, wherein the RRAM stack is set over the drain region and away from the HKMG gate structure;
a third dielectric layer, disposed over the second dielectric layer, wherein the third dielectric layer covers side surfaces and a top surface of the RRAM stack; and
three contact holes, wherein a first contact hole penetrates the third dielectric layer and the hard mask layer in the RRAM stack exposing the top electrode, a second contact hole penetrates the third dielectric layer and the second dielectric layer exposing the HKMG gate structure, and a third contact hole penetrates the third dielectric layer, the second dielectric layer, the first dielectric layer, and the protective layer exposing the source region.

9. The semiconductor structure according to claim 8, wherein a material of the top electrode comprises TiN, wherein the top electrode and a high-resistance layer of the HKMG gate structure are made of same materials, wherein a material of the bottom electrode comprises TiN, TaN or W, wherein a material of the resistive switching layer comprises HfO₂, Al₂O₃, TaO₂ or Ta₂O₅.

10. The semiconductor structure according to claim 8, wherein a thickness of the top electrode ranges from 30 Å to 100 Å, a thickness of the resistive switching layer ranges from 20 Å to 100 Å, and a thickness of the bottom electrode ranges from 300 Å to 600 Å.
